(19) United States
(12) Patent Application Publication
(10) Pub. No.: US 2026/0075969 A1
(43) Pub. Date: Mar. 12, 2026

(54) IMAGE SENSOR CHIP AND SEMICONDUCTOR PACKAGE INCLUDING THE SAME

(71) Applicant: SAMSUNG ELECTRONICS CO., LTD., Suwon-si (KR)

(72) Inventors: SANG-UK HAN, Suwon-si (KR); KYONGSOON CHO, Suwon-si (KR)

(21) Appl. No.: 19/056,398

(22) Filed: Feb. 18, 2025

(30) Foreign Application Priority Data
Sep. 10, 2024 (KR) 10-2024-0123201

(51) Int. Cl. H10F 39/00

(52) U.S. Cl. CPC H10F 39/804; H10F 39/8057; H10F 39/8063; H10F 39/811

(57) ABSTRACT

A semiconductor package includes a package substrate and an image sensor chip on the package substrate. The image sensor chip includes a semiconductor substrate, a light-shielding pattern on the semiconductor substrate, a plurality of microlenses on the light-shielding pattern, and a first protection pattern on the plurality of microlenses. The light-shielding pattern extends in a first direction parallel to a top surface of the semiconductor substrate. A portion of a top surface of the light-shielding pattern is exposed by the first protection pattern.

### CROSS-REFERENCE TO RELATED APPLICATIONS

This application claims priority under 35 U.S. C § 119 to Korean Patent Application No. 10-2024-0123201 filed on Sep. 10, 2024 in the Korean Intellectual Property Office, the disclosure of which is hereby incorporated by reference in its entirety.

### BACKGROUND

The present inventive concepts relate to a semiconductor package, and more particularly, to a semiconductor package including an image sensor chip.

Image sensors, such as CCD sensors or CMOS image sensors, are used in various electronic products, such as mobile phones, digital cameras, optical mice, security cameras, and biometric recognition devices. As electronic products are miniaturized and multi-functionalized, a semiconductor package including an image sensor requires miniaturization/high density, low power consumption, multi-functionality, high-speed signal processing, improved reliability, low price, and sharp image quality. Various studies are being performed to meet such requirements.

### SUMMARY OF THE INVENTION

Some embodiments of the present inventive concepts provide an image sensor chip with improved reliability and structural stability and a semiconductor package including the same.

An object of the present inventive concepts is not limited to the mentioned above, and other objects which have not been mentioned above will be clearly understood to those skilled in the art from the following description.

According to some embodiments of the present inventive concepts, a semiconductor package includes a package substrate; and an image sensor chip on the package substrate. The image sensor chip includes a semiconductor substrate; a light-shielding pattern on the semiconductor substrate; a plurality of microlenses on the light-shielding pattern; and a first protection pattern on the plurality of microlenses. The light-shielding pattern extends in a first direction parallel to a top surface of the semiconductor substrate. A portion of a top surface of the light-shielding pattern is exposed by the first protection pattern.

According to some embodiments of the present inventive concepts, a semiconductor package includes a package substrate; an image sensor chip on the package substrate; a transparent substrate on the image sensor chip; and a dam structure on an edge of the image sensor chip and between the image sensor chip and the transparent substrate. The image sensor chip includes a semiconductor substrate; a light-shielding pattern on the semiconductor substrate; an upper planarization layer on the light-shielding pattern; a plurality of microlenses on the upper planarization layer; and a first protection pattern on the plurality of microlenses and a lateral surface of the upper planarization layer. The dam structure has a first lateral surface and an opposite second lateral surface. The first lateral surface is closer than the second lateral surface to the plurality of microlenses. A distance in a first direction from the second lateral surface to the first protection pattern has a first length. The first direction may be parallel to a top surface of the semiconductor substrate. A distance in the first direction from the first lateral surface to the first protection pattern has a second length. The second length may be about 20% to about 35% of the first length.

According to some embodiments of the present inventive concepts, a semiconductor package includes a package substrate; an image sensor chip on the package substrate; a transparent substrate on the image sensor chip; and a dam structure on an edge of the image sensor chip and between the image sensor chip and the transparent substrate. The image sensor chip includes a semiconductor substrate that has a pixel array region and a pad region extending around a periphery of the pixel array region, wherein the pixel array region includes a light-receiving section and a light-shielding section between the light-receiving section and the pad region; a light-shielding pattern on the light-shielding section; an upper planarization layer on the light-receiving section and the light-shielding section, wherein the upper planarization layer is on a portion of the light-shielding pattern; a plurality of microlenses on the upper planarization layer; and a first protection pattern that is on the plurality of microlenses and a lateral surface of the upper planarization layer. The first protection pattern extends onto the light-shielding section. One end of the first protection pattern may be between the plurality of microlenses and the dam structure.

### BRIEF DESCRIPTION OF DRAWINGS

FIG. 1 illustrates a plan view showing an image sensor according to some embodiments of the present inventive concepts.

FIG. 2 illustrates a cross-sectional view taken along line I-I′ of FIG. 1.

FIG. 3 illustrates an enlarged view showing section PP of FIG. 2.

FIG. 4 illustrates an enlarged view showing section CU1 of FIG. 3.

FIG. 5 illustrates a cross-sectional view showing an image sensor according to some embodiments of the present inventive concepts.

FIGS. 6, 7, 8, 9, and 10 illustrate cross-sectional views showing a method of fabricating an image sensor according to some embodiments of the present inventive concepts.

### DETAILED DESCRIPTION OF EMBODIMENTS

The following will now describe in detail some embodiments of the present inventive concepts with reference to the accompanying drawings.

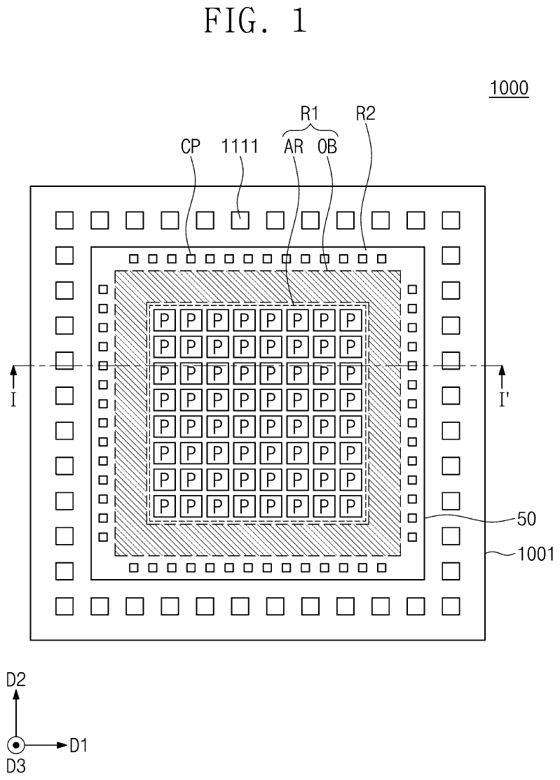

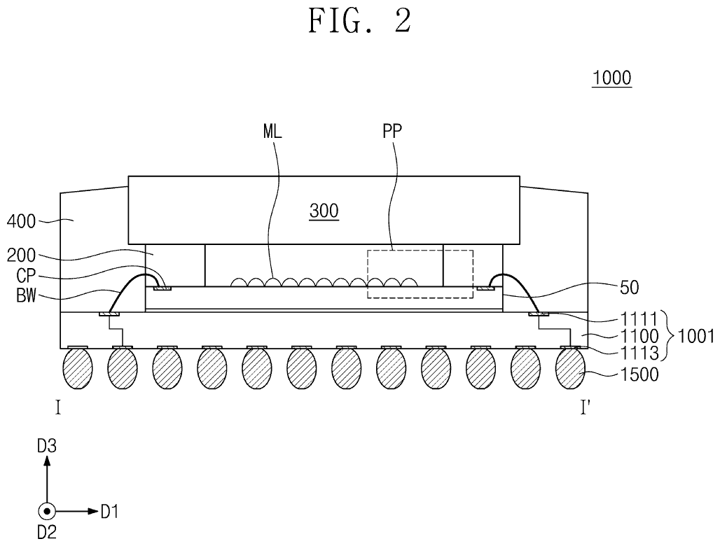

FIG. 1 illustrates a plan view showing an image sensor according to some embodiments of the present inventive concepts. FIG. 2 illustrates a cross-sectional view taken along line I-I′ of FIG. 1.

Referring to FIGS. 1 and 2, a semiconductor package 1000 according to some embodiments of the present inventive concepts may include a package substrate 1001, an image sensor chip 50, a dam structure 200, and a transparent substrate 300, and a molding layer 400.

The package substrate 1001 may be, for example, a printed circuit board (PCB). The package substrate 1001 may include a base substrate 1100, bonding pads 1111 disposed on a top surface of the base substrate 1100, and bonding pads 1113 disposed on a bottom surface of the base substrate 1100. The base substrate 1100 may include a single-layered inner line or multi-layered inner lines.

The bonding pads 1111 may be electrically connected through the inner wiring lines to the bonding pads 1113. The bonding pads 1111 may be electrically connected to metallic bonding wires BW to conductive pads CP of the image sensor chip 50.

The bonding pads 1111 may be disposed on an edge of the base substrate 1100. The bonding pads 1111 may be placed around the image sensor chip 50 mounted on the package substrate 1001. FIG. 1 depicts that the bonding pads 1111 are placed in one row while surrounding the image sensor chip 50, but the present inventive concepts are not limited thereto. For example, the bonding pads 1111 may be placed in two rows while surrounding the image sensor chip 50. For another example, the bonding pads 1111 may be placed on opposite sides of the image sensor chip 50.

The bonding pads 1113 may be attached thereto with connection terminals 1500 such as solder balls or solder bumps.

The image sensor chip 50 may be disposed on the package substrate 1001. The image sensor chip 50 may be attached through an adhesive layer or a bonding tape to a top surface of the package substrate 1001.

The image sensor chip 50 may include a pixel array region R1 and a pad region R2 that surrounds the pixel array region R1.

The pixel array region R1 may include a plurality of unit pixels P that are two-dimensionally arranged along a first direction D1 and a second direction D2 that intersect each other.

In this description, the first direction D1 may be defined to refer to one direction parallel to the top surface of the package substrate 1001. The second direction D2 may be defined to refer to one direction parallel to the top surface of the package substrate 1001 and orthogonal to the first direction D1. A third direction D3 may be defined to refer to a direction perpendicular to the top surface of the package substrate 1001.

Each of the unit pixels P may include a photoelectric conversion element and readout elements. Each unit pixel P of the pixel array region R1 may output electrical signals converted from incident light.

The pixel array region R1 may include a light-receiving section AR and a light-shielding section OB. The light-shielding section OB may be provided between the light-receiving section AR and the pad region R2. When viewed in plan, the light-shielding section OB may surround the light-receiving section AR (i.e., the light-shielding section OB extends around the periphery of the light-receiving section AR. For example, when viewed in plan, the light-shielding section OB may be disposed on an upside, a downside, a left-side, and a right-side of the light-receiving section AR.

The light-shielding section OB may include reference pixels on which no light is incident, and an amount of charges sensed in the unit pixels P of the light-receiving section AR may be compared with a reference amount of charges occurring at reference pixels, which may result in calculation of magnitude of electrical signals sensed in the unit pixels P.

The pad region R2 may include a plurality of conductive pads CP used for input and output of control signals, photoelectric conversion signals, and so forth. For easy connection with external devices, when viewed in plan, the pad region R2 may surround the pixel array region R1 (i.e., the pad region R2 extends around the periphery of the pixel array region R1). The conductive pads CP may allow an external device to receive electrical signals generated from the unit pixels P. The conductive pads CP may be connected through the bonding wires BW to the package substrate 1001. Alternatively, according to some embodiments, a flip chip bonding using solder balls or solder bumps may be used to connect the conductive pads CP of the image sensor chip 50 to the package substrate 1001.

Microlenses ML may be disposed on the image sensor chip 50. The microlenses ML may concentrate externally incident light. Each of the microlenses ML may have a convex shape and a predetermined curvature radius. The microlenses ML may be two-dimensionally arranged along the first direction D1 and the second direction D2, and may be disposed corresponding to the unit pixels P.

The dam structure 200 may be disposed between the image sensor chip 50 and the transparent substrate 300. The dam structure 200 may be placed on an edge of the image sensor chip 50 to cover the conductive pads CP. The dam structure 200 may have a closed loop shape.

The dam structure 200 may rigidly place the transparent substrate 300, and may separate the image sensor chip 50 and the transparent substrate 300 from each other. For example, the dam structure 200 may provide an empty space between the transparent substrate 300 and the image sensor chip 50. The dam structure 200 may close the empty space between the transparent substrate 300 and the image sensor chip 50 to prevent the empty space from the infiltration of moisture or foreign substances from the outside. In this case, the microlenses ML may not vertically overlap the dam structure 200.

The dam structure 200 may include a dielectric material. For example, the dam structure 200 may include at least one selected from epoxy resin, polyimide, and resist. The dam structure 200 may include a dry film resist (DFR) or a dielectric material.

The dam structure 200 may separate the transparent substrate 300 from the image sensor chip 50. The transparent substrate 300 may be formed of transparent glass, transparent resin, or transparent ceramic. The transparent substrate 300 may have a width and a thickness greater than those of the image sensor chip 50.

The molding layer 400 may be disposed on the package substrate 1001, and may encapsulate the image sensor chip 50, the bonding wires BW, and the transparent substrate 300. For example, from the top surface of the package substrate 1001, the molding layer 400 may cover a lateral surface of the image sensor chip 50 and a lateral surface of the transparent substrate 300, as illustrated in FIG. 2. The molding layer 400 may have a closed loop shape when viewed in plan.

The molding layer 400 may cover the bonding wires BW and an outer lateral surface of the dam structure 200. The molding layer 400, together with the dam structure 200, may prevent the image sensor chip 50 from being contaminated with foreign substances. In addition, the molding layer 400 may protect the semiconductor package 1000 from external compact (i.e., the molding layer 400 protects the semiconductor package 1000 from external forces, such as compression forces, etc., that may damage the semiconductor package 1000).

The molding layer 400 may have an inclined top surface, and the inclined top surface may be lower than a top surface of the transparent substrate 300, as illustrated in FIG. 2. Alternatively, the molding layer 400 may have a top surface located at substantially the same plane as that of a top surface of the transparent substrate 300. The molding layer 400 may be formed of, for example, an epoxy molding compound (EMC).

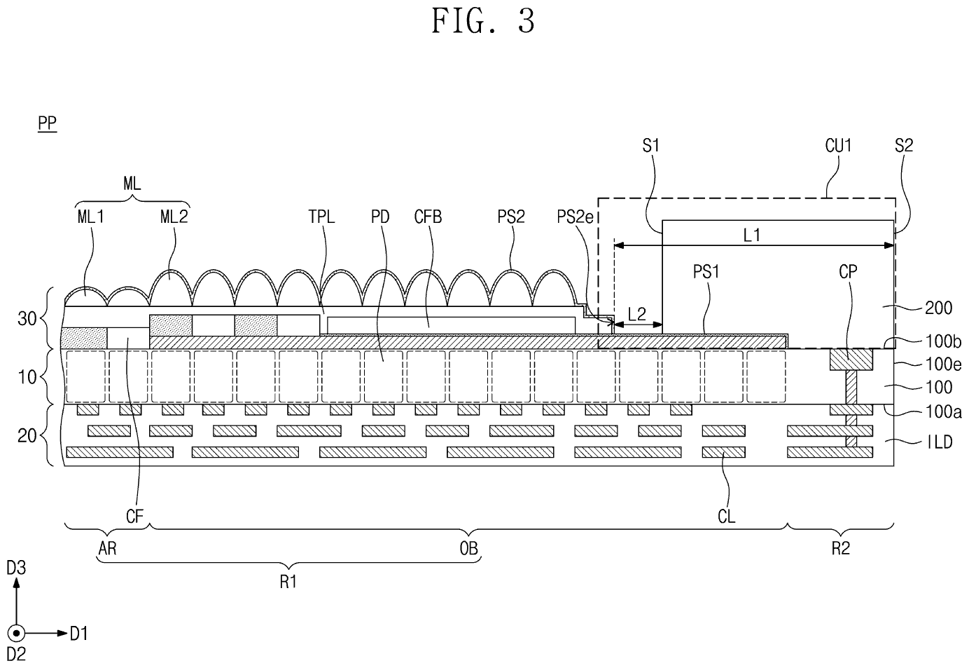

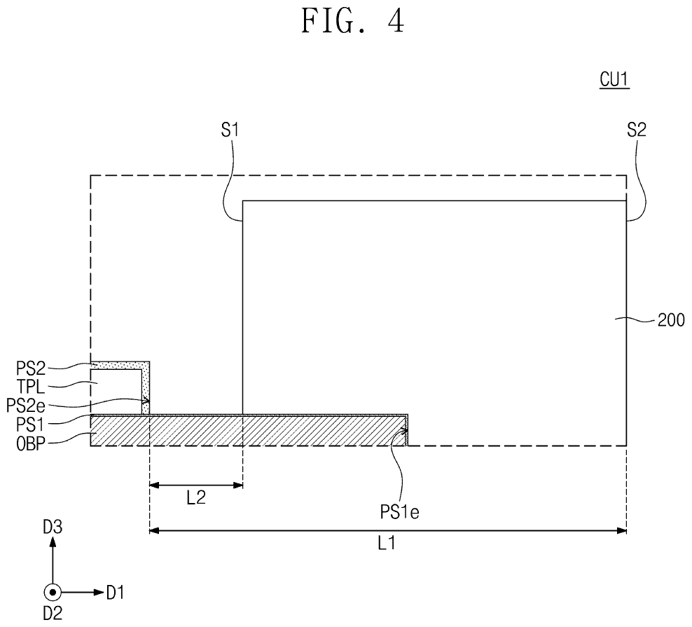

FIG. 3 illustrates an enlarged view showing section PP of FIG. 2. FIG. 4 illustrates an enlarged view showing section CU1 of FIG. 3.

Referring to FIGS. 1, 3, and 4, when viewed in a vertical direction, the image sensor chip 50 may include a photoelectric conversion layer 10, a readout circuit layer 20, and an optical transmission layer 30.

When viewed in a vertical direction, the photoelectric conversion layer 10 may be disposed between the readout circuit layer 20 and the optical transmission layer 30. The photoelectric conversion layer 10 may include a semiconductor substrate 100 and photoelectric conversion elements PD provided in the semiconductor substrate 100.

The semiconductor substrate 100 may be doped with first impurities to have a first conductivity type. The first impurities may be, for example, boron. The first conductivity type may be of, for example, p-type.

The semiconductor substrate 100 may have a first surface 100a and a second surface 100b that are opposite to each other. The second surface 100b may receive light incident on the semiconductor substrate 100. The semiconductor substrate 100 may be a monocrystalline wafer, an epitaxial layer, or a silicon-on-insulator (SOI) substrate each of which includes one or both of silicon and germanium.

The photoelectric conversion element PD may be doped with second impurities to have a second conductivity type different from the first conductivity type. The second impurities may be, for example, phosphorus or arsenic. The second conductivity type may be of, for example, n-type.

On the pad region R2, conductive pads CP may be provided on a location adjacent to an edge 100e of the semiconductor substrate 100. Electrical signals may be transmitted through the conductive pads CP between the unit pixels P and an external device.

The readout circuit layer 20 may be disposed on the first surface 100a of the semiconductor substrate 100. The readout circuit layer 20 may include readout circuits (e.g., metal oxide semiconductor (MOS) transistors) connected to the photoelectric conversion layer 10. The readout circuit layer 20 may signally process the electrical signals converted in the photoelectric conversion layer 10. The readout circuit layer 20 may include pixel transistors such as a reset transistor, a source follower transistor, and a selection transistor.

For example, the readout circuit layer 20 may include MOS transistors disposed on a bottom surface of the semiconductor substrate 100, connection lines CL coupled to the MOS transistors, and interlayer dielectric layers ILD interposed between the connection lines CL. The connection lines CL may be provided in the form of a multiple layers, and the connection lines CL located at different levels may be connected to each other through contact plugs.

The optical transmission layer 30 may be disposed on the second surface 100b of the semiconductor substrate 100. The optical transmission layer 30 may include color filters CF, a light-shielding pattern OBP (FIG. 4), an upper planarization layer TPL, microlenses ML, a first protection pattern PS1, and a second protection pattern PS2.

On the light-receiving section AR and the light-shielding section OB, the color filters CF may be disposed on the second surface 100b of the semiconductor substrate 100. The color filters CF may be disposed corresponding to the photoelectric conversion elements PD. The color filters CF disposed on the light-shielding section OB may be provided to correspond to only some of the photoelectric conversion elements PD. Based on the unit pixel P, the color filter CF may include one of red, green, and blue filters or one of magenta, cyan, and yellow color filters.

On the light-shielding section OB, the light-shielding pattern OBP may be disposed on the second surface 100b of the semiconductor substrate 100. The light-shielding pattern OBP may extend in the first direction D1.

The color filters CF disposed on the light-shielding section OB may be disposed on the light-shielding pattern OBP. The light-shielding pattern OBP may cause the color filters CF disposed on the light-shielding section OB to have their top surfaces located at a higher level than that of top surfaces of the color filters CF disposed on the light-receiving section AR.

The light-shielding pattern OBP may block incidence of light on the semiconductor substrate 100. The light-shielding pattern OBP may include one or more of metal and metal nitride. For example, the light-shielding pattern OBP may include one or both of titanium and titanium nitride.

The first protection pattern PS1 may cover a top surface and a lateral surface of the light-shielding pattern OBP. The first protection pattern PS1 may extend in the first direction D1. A portion of the first protection pattern PS1 may be in contact with the dam structure 200. The first protection pattern PS1 may include, for example, aluminum oxide. A thickness of the first protection pattern PS1 may range, for example, from about 10 nm to about 20 nm.

On the light-shielding section OB, a bulk filtering layer CFB may be provided on the light-shielding pattern OBP and the first protection pattern PS1. The bulk filtering layer CFB may block light whose wavelength is different from that of light produced from the color filters CF. For example, the bulk filtering layer CFB may block an infrared ray. The bulk filtering layer CFB may include a blue color filter, but the present inventive concepts are not limited thereto.

On the light-receiving section AR and the light-shielding section OB, the upper planarization layer TPL may be disposed on the color filters CF and the light-shielding pattern OBP. For example, the upper planarization layer TPL may cover the color filters CF and the bulk filtering layer CFB. The first protection pattern PS1 may be provided between the upper planarization layer TPL and the light-shielding pattern OBP. The upper planarization layer TPL may have a stepwise structure on a lateral surface in the vicinity of a location adjacent to the pad region R2.

The upper planarization layer TPL may include a transparent dielectric material. The upper planarization layer TPL may include an organic material such as polymer. For example, the upper planarization layer TPL may include glass, epoxy resin, silicon resin, polyurethane, any arbitrary suitable materials, or a combination thereof. Alternatively, the upper planarization layer TPL may include silicon oxide or silicon oxynitride.

The microlenses ML may be disposed on the upper planarization layer TPL. Each of the microlenses ML may have a convex shape with a certain curvature radius. The microlenses ML may include first microlenses ML1 disposed on the light-receiving section AR and second microlenses ML2 disposed on the light-shielding section OB. The second microlenses ML2 may be, for example, dummy microlenses. The second microlenses ML2 may have their top surfaces at a level higher than that of top surfaces of the first microlenses ML1.

The second protection pattern PS2 may conformally cover the microlenses ML. Referring to FIG. 4, the second protection pattern PS2 may extend from top surfaces of the microlenses ML to cover the lateral surface of the upper planarization layer TPL. For example, the second protection pattern PS2 may extend to the light-receiving section AR and a portion of the light-shielding section OB to cover the stepwise structure on the lateral surface of the upper planarization layer TPL. A portion of a top surface of the light-shielding pattern OBP may be exposed from the second protection pattern PS2 (i.e., a portion of the top surface of the light-shielding pattern OBP is not covered by the second protection pattern PS2, as illustrated in FIG. 4).

A bottom surface of the second protection pattern PS2 may be located at a level higher than that of the top surface of the light-shielding pattern OBP. The bottom surface of the second protection pattern PS2 may be spaced apart from the semiconductor substrate 100. In this description, the bottom surface of the second protection pattern PS2 may correspond to a lowermost surface of the second protection pattern PS2. One end PS1e of the first protection pattern PS1 may be positioned closer than one end PS2e of the second protection pattern PS2 to the edge 100e of the semiconductor substrate 100.

The conductive pad CP may be positioned closer to the first protection pattern PS1 than to the second protection pattern PS2. The dam structure 200 may be spaced apart in the first direction D1 from the second protection pattern PS2. The one end PS2e of the second protection pattern PS2 may be positioned between the microlenses ML and the dam structure 200. The one end PS1e of the first protection pattern PS1 may be positioned closer than the one end PS2e of the second protection pattern PS2 to the edge 100e of the semiconductor substrate 100.

The dam structure 200 may have a first lateral surface S1 and an opposite second lateral surface S2 that face away from each other, as illustrated in FIG. 4. The first lateral surface S1 may correspond to an inner lateral surface of the dam structure 200. The second lateral surface S2 may correspond to an outer lateral surface of the dam structure 200. The first lateral surface S1 may be closer than the second lateral surface S2 to the microlenses ML. The first lateral surface S1 may be positioned between the one end PS2e of the second protection pattern PS2 and the lateral surface of the light-shielding pattern OBP. The one end PS1e of the first protection pattern PS1 may be positioned between the one end PS2e of the second protection pattern PS2 and the second lateral surface S2 of the dam structure 200.

A first length L1 may be defined as a spacing distance in the first direction D1 from the second lateral surface S2 of the dam structure 200 to the second protection pattern PS2. For example, the first length L1 may correspond to a spacing distance in the first direction D1 from the edge 100e of the semiconductor substrate 100 to the second protection pattern PS2. A first length L2 may be defined as a spacing distance in the first direction D1 from the first lateral surface S1 of the dam structure 200 to the second protection pattern PS2. The second length L2 may be about 20% to about 35% of the first length L1. For example, the first length L1 may range from about 450 μm to about 500 μm. The second length L2 may range from about 100 μm to about 150 μm.

A thickness of the second protection pattern PS2 may range, for example, from about 100 nm to about 120 nm. The second protection pattern PS2 may include at least one selected from silicon oxide, titanium oxide, zirconium oxide, and hafnium oxide.

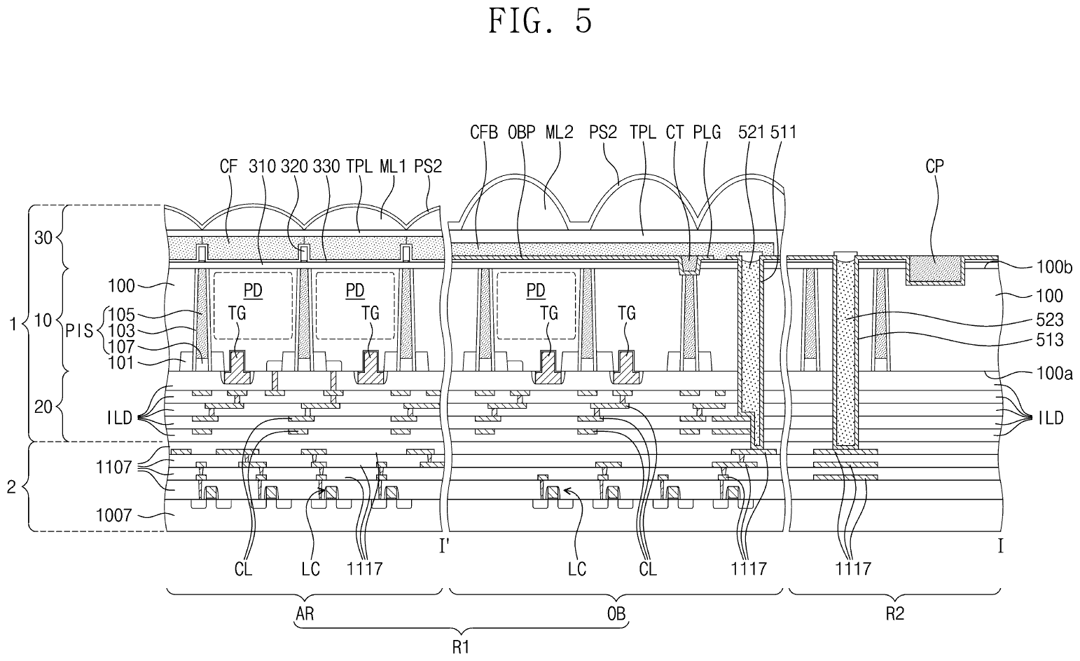

FIG. 5 illustrates a cross-sectional view showing an image sensor according to some embodiments of the present inventive concepts. Omission will be made to avoid the explanation of that discussed in FIGS. 1 to 4.

Referring to FIG. 5, the image sensor chip 50 may include a sensor part 1 and a logic part 2 on the sensor part 1. When viewed in a vertical direction, as discussed above, the sensor part 1 may include the photoelectric conversion layer 10 between the readout circuit layer 20 and the optical transmission layer 30.

On each of pixel areas, a device isolation layer 101 may be disposed adjacent to the first surface 100a of the semiconductor substrate 100. The device isolation layer 101 may define an active area on the first surface 100a of the semiconductor substrate 100. The device isolation layer 101 may include a dielectric material.

The semiconductor substrate 100 may be provided therein with separation structures PIS that divide the photoelectric conversion elements PD from each other. The separation structure PIS may vertically extend from the first surface 100a to the second surface 100b of the semiconductor substrate 100. The separation structure PIS may penetrate a portion of the device isolation layer 101.

The separation structure PIS may include a liner dielectric pattern 103, a semiconductor pattern 105, and a buried dielectric pattern 107. The semiconductor pattern 105 may include, for example, impurity-doped polysilicon or metal.

The liner dielectric pattern 103 may be provided between the semiconductor pattern 105 and the semiconductor substrate 100. The buried dielectric pattern 107 may be disposed below the semiconductor pattern 105. The liner dielectric pattern 103 and the buried dielectric pattern 107 may include silicon oxide.

On the light-shielding section OB, the semiconductor pattern 105 may be connected to a bias contact plug PLG. The bias contact plug PLG may include metal and/or metal nitride. For example, the bias contact plug PLG may include titanium and/or titanium nitride.

A contact pattern CT may be buried in a contact hole formed in which the bias contact plug PLG is formed. The contact pattern CT may include a material different from that of the bias contact plug PLG. For example, the contact pattern CT may include aluminum (Al).

A negative bias may be applied to the semiconductor pattern 105 through the contact pattern CT and the bias contact plug PLG. The negative bias may be transmitted from the light-shielding section OB to the light-receiving section AR. As the negative bias is applied to the semiconductor pattern 105 of the separation structure PIS, it may be possible to reduce a dark current generated from a boundary between the separation structure PIS and the semiconductor substrate 100.

Transfer gate electrodes TG may be disposed on the first surface 100a of the semiconductor substrate 100. A portion of the transfer gate electrode TG may protrude into the semiconductor substrate 100, and a gate dielectric layer may be interposed between the transfer gate electrode TG and the semiconductor substrate 100. The gate dielectric layer may be formed of silicon oxide, silicon oxynitride, high-k dielectric whose dielectric constant is greater than that of silicon oxide, or a combination thereof.

A floating diffusion area may be provided in the semiconductor substrate 100 on one side of the transfer gate electrode TG. The floating diffusion area may be formed by implanting the semiconductor substrate 100 with impurities whose conductivity type is opposite to that of semiconductor substrate 100. For example, the floating diffusion area may be an n-type impurity area.

On the first surface 100a of the semiconductor substrate 100, the interlayer dielectric layers ILD may cover the transfer gate electrodes TG and the pixel transistors.

The optical transmission layer 30 may be disposed on the second surface 100b of the semiconductor substrate 100. For example, the optical transmission layer 30 may include a lower planarization dielectric layer 310, a grid 320, a protection layer 330, the color filters CF, the light-shielding pattern OBP, the first and second microlenses ML1 and ML2, and the second protection pattern PS2.

The lower planarization dielectric layer 310 may cover the second surface 100b of the semiconductor substrate 100. The lower planarization dielectric layer 310 may extend from the light-receiving section AR toward the light-shielding section OB and the pad region R2. The lower planarization dielectric layer 310 may be formed of a transparent dielectric material and may include a plurality of layers. The lower planarization dielectric layer 310 may be formed of a dielectric material whose refractive index is different from that of the semiconductor substrate 100. The lower planarization dielectric layer 310 may include metal oxide and/or silicon oxide.

The lower planarization dielectric layer 310 may be a single layer or a multiple layer. For example, the lower planarization dielectric layer 310 may include one of metal oxide and metal fluoride each of which includes at least one metal selected from hafnium (Hf), zirconium (Zr), aluminum (Al), tantalum (Ta), titanium (Ti), yttrium (Y), and lanthanide (e.g., Ln). For example, the lower planarization dielectric layer 310 may include aluminum oxide or hafnium oxide.

The grid 320 may be disposed on the lower planarization dielectric layer 310. The grid 320 may include a light-shielding pattern and/or a low-refractive pattern. The light-shielding pattern may include a metallic material, such as titanium, tantalum, or tungsten. The low-refractive pattern may be formed of a material whose refractive index is less than that of the light-shielding pattern. The low-refractive pattern may be formed of an organic material and may have a refractive index of about 1.1 to about 1.3.

The protection layer 330 may cover the lower planarization dielectric layer 310 and the grid 320. The protection layer 330 may include at least one selected from aluminum oxide and silicon oxide. The protection layer 330 may extend from the light-receiving section AR to the light-shielding section OB and the pad region R2.

The color filters CF may be disposed corresponding to pixel areas. Based on a unit pixel, the color filter CF may include one of red, green, and blue filters or one of magenta, cyan, and yellow color filters.

On the light-shielding section OB, a first through conductive pattern 511 may penetrate the semiconductor substrate 100 to come into electrical connection with the connection lines CL of the readout circuit layer 20 and a wiring structure 1117 of the logic part 2. The first through conductive pattern 511 may have a first bottom surface and a second bottom surface that are located at different levels. A first buried pattern 521 may be provided in the first through conductive pattern 511. The first buried pattern 521 may include a low-refractive material and may have dielectric properties.

On the pad region R2, the conductive pads CP may be provided on the second surface 100b of the semiconductor substrate 100. The conductive pads CP may be buried in the second surface 100b of the semiconductor substrate 100. For example, on the pad region R2, the conductive pads CP may be provided in pad trenches formed on the second surface 100b of the semiconductor substrate 100. The conductive pads CP may include metal, such as aluminum, copper, tungsten, titanium, tantalum, or an alloy thereof. The conductive pads CP may be electrically connected through bonding wires to an external apparatus.

On the pad region R2, a second through conductive pattern 513 may penetrate the semiconductor substrate 100 to come into electrical connection with the wiring structure 1117 of the logic part 2. The second through conductive pattern 513 may extend onto the second surface 100b of the semiconductor substrate 100 to come into electrical connection with the conductive pads CP. A portion of the second through conductive pattern 513 may cover bottom surfaces and sidewalls of the conductive pads CP. A second buried pattern 523 may be provided in the second through conductive pattern 513. The second buried pattern 523 may include a low-refractive material and may have dielectric properties. On the pad region R2, the separation structures PIS may be provided around the second through conductive pattern 513.

The logic part 2 may be disposed adjacent to the readout circuit layer 20 of the sensor part 1. The logic part 2 may include a power circuit, an input/output interface, and an image signal processor. The logic part 2 may include a logic semiconductor substrate 1007, logic circuits LC, wiring structures 1117 connected to the logic circuits LC, and logic interlayer dielectric layers 1107. An uppermost one of the logic interlayer dielectric layers 1107 may be in contact with the readout circuit layer 20 of the sensor part 1. The logic part 2 may be electrically connected to the sensor part 1 through the first through conductive pattern 511 and the second through conductive pattern 513.

In an embodiment, it is explained that the sensor part 1 and the logic part 2 are electrically connected through the first and second through conductive patterns 511 and 513, but the present inventive concepts are not limited thereto. According to some embodiments, it may be possible to omit the first and second through conductive patterns 511 and 513 shown in FIG. 5, and in this case, bonding pads may be coupled to each other to electrically connect the sensor part 1 to the logic part 2.

A semiconductor package according to a comparative example may include a light-shielding pattern, a first protection pattern covering the light-shielding pattern, a plurality of microlenses, and a second protection covering the plurality of microlenses. The second protection pattern may extend from the plurality of microlenses to the first protection pattern and an edge of a semiconductor substrate, and may cover the first protection pattern and the edge of the semiconductor substrate. As a result, under a high temperature environment, the second protection may be delaminated from the first protection pattern, and thus, the semiconductor package may have reduced structural stability.

In contrast, in a semiconductor package according to some embodiments of the present inventive concepts, the light-shielding pattern may be exposed from the second protection pattern. For example, the second protection pattern may not cover the edge of the semiconductor substrate adjacent to a dam structure, and may be spaced apart at about 450 μm to about 500 μm from the edge of the semiconductor substrate. In conclusion, even under a high temperature environment, on an area adjacent to the edge of the semiconductor substrate, the first protection pattern and the second protection pattern may be prevented from delamination, which may result in an improvement in structural stability of the semiconductor package.

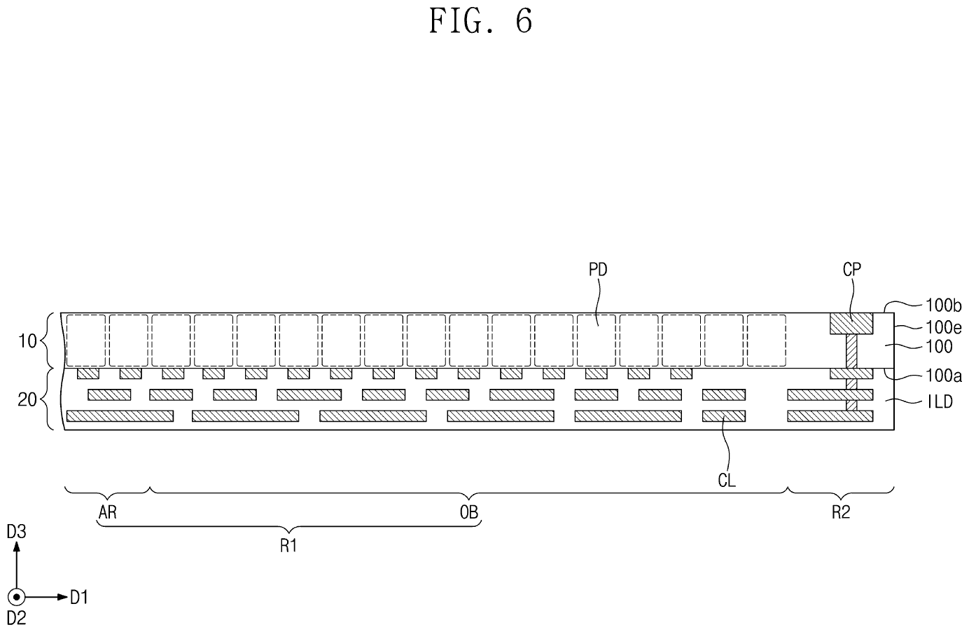

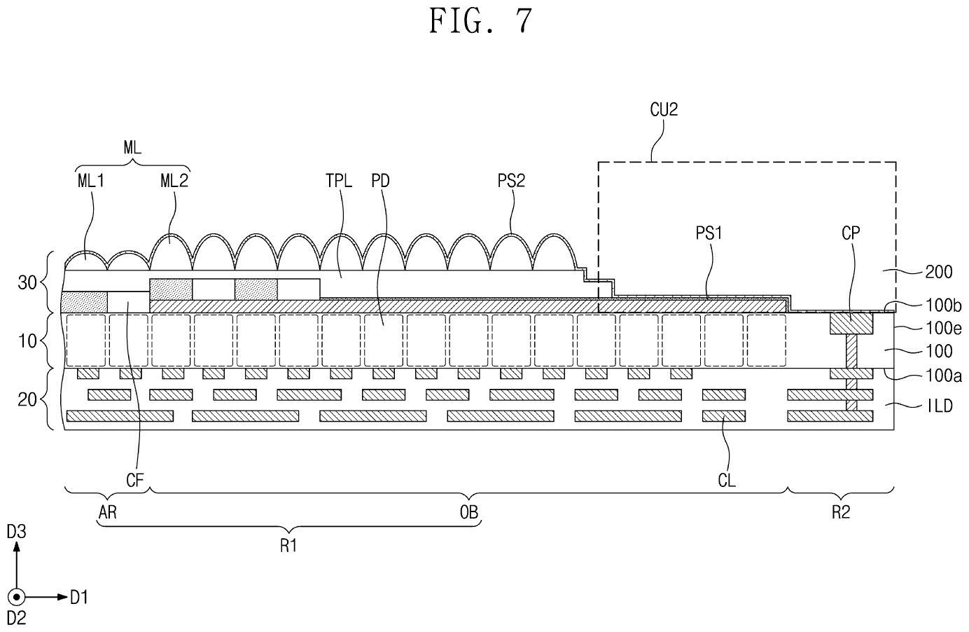

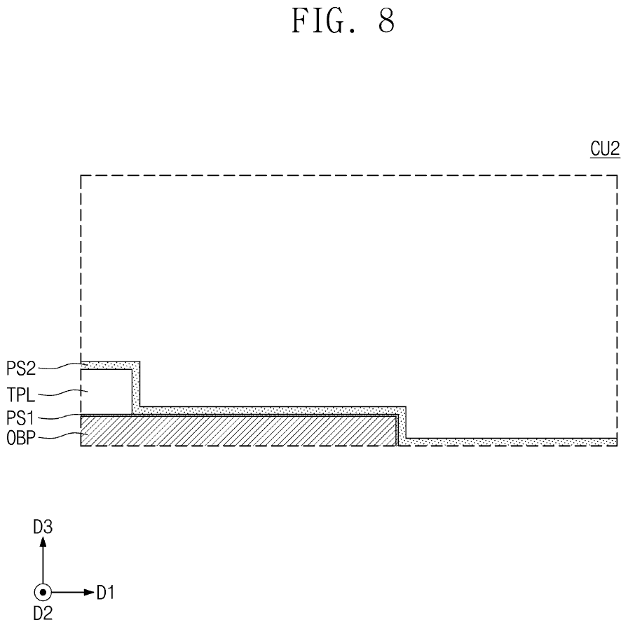

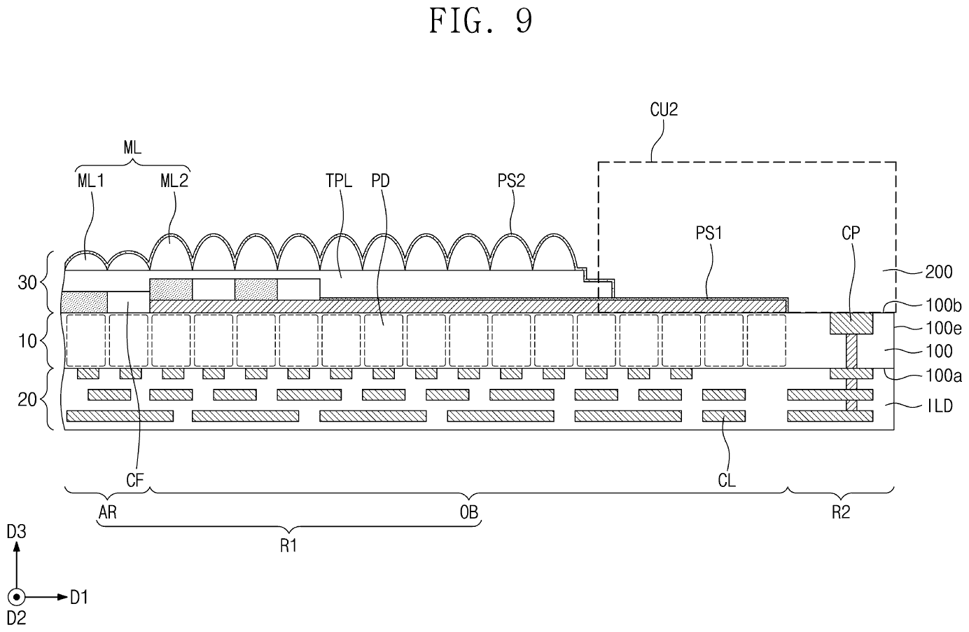

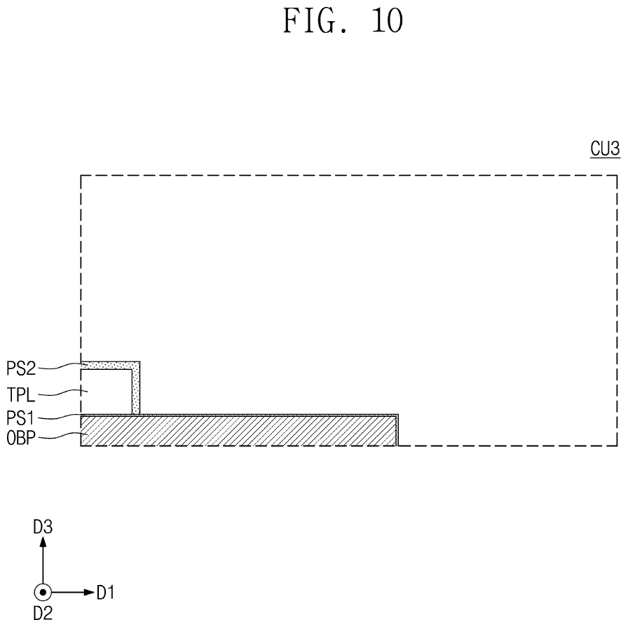

FIGS. 6, 7, 8, 9, and 10 illustrate cross-sectional views showing a method of fabricating an image sensor according to some embodiments of the present inventive concepts. FIG. 8 illustrates an enlarged view showing section CU2 of FIG. 7. FIG. 10 illustrates an enlarged view showing section CU3 of FIG. 9.

Referring to FIGS. 3 and 6, a semiconductor substrate 100 may be provided which includes a pixel array region R1 and a pad region R2. The pixel array region R1 may include a light-receiving section AR and a light-shielding section OB. The semiconductor substrate 100 may have a first surface 100a and a second surface 100b that are opposite to each other. A conductive pad CP may be formed on the pad region R2. An ion implantation process may be employed to form a photoelectric conversion element PD in the semiconductor substrate 100. As the photoelectric conversion element PD is formed, a photoelectric conversion layer 10 may be formed.

Afterwards, a readout circuit layer 20 including an interlayer dielectric layer ILD and connection lines CL may be formed on the photoelectric conversion layer 10.

Referring to FIGS. 7 and 8, on the light-shielding section OB, a light-shielding pattern OBP may be formed on the semiconductor substrate 100. On the light-receiving section AR, a color filter CF may be formed on the semiconductor substrate 100. On the light-shielding section OB, a color filter CF and a first protection pattern PS1 may be formed on the light-shielding pattern OBP. The first protection pattern PS1 may cover a top surface and a lateral surface of the light-shielding pattern OBP.

On the light-receiving section AR and the light-shielding section OB, an upper planarization layer TPL may be formed on the color filter CF. A plurality of microlenses ML may be formed on the upper planarization layer TPL. The microlenses ML may include a first plurality of microlenses ML1 on the light-receiving section AR and a second plurality of microlenses ML2 on the light-shielding section OB.

A second protection pattern PS2 may cover the microlenses ML. For example, as shown in FIG. 8, the second protection pattern PS2 may cover the microlenses ML, and may also cover a lateral surface of the upper planarization layer TPL, the first protection pattern PS1, and an edge 100e of the semiconductor substrate 100. The second protection pattern PS2 may extend from the microlenses ML to the edge 100e of the semiconductor substrate 100. As the second protection pattern PS2 is formed, an optical transmission layer 30 may be formed on the photoelectric conversion layer 10.

Referring to FIGS. 9 and 10, a patterning process may be performed on a portion of the second protection pattern PS2. For example, the patterning process may remove the second protection pattern PS2 on the first protection pattern PS1 and the edge 100e of the semiconductor substrate 100.

As a result of the patterning process, the second protection pattern PS2 may cover only the microlenses ML and the lateral surface of the upper planarization layer TPL, and a portion of the top surface of the light-shielding pattern OBP may be exposed from the second protection pattern PS2.

Thereafter, referring back to FIGS. 2 and 5, a logic part 2 may be coupled to the readout circuit layer 20 to eventually form an image sensor chip 50. The image sensor chip 50 may be mounted on a package substrate 1001, and then a dam structure 200 may be used to rigidly place a transparent substrate 300. A molding layer 400 may be formed on the package substrate 1001 to cover the image sensor chip 50 and a lateral surface of the transparent substrate 300, leading to completion of a semiconductor package according to some embodiments of the present inventive concepts.

In a semiconductor package according to some embodiments of the present inventive concepts, an image sensor chip may include a light-shielding pattern, a first protection pattern covering the light-shielding pattern, a plurality of microlenses, and a second protection pattern covering the microlenses. A top surface of the light-shielding pattern may be partially exposed from the second protection pattern, and the second protection pattern may not cover an edge of a semiconductor substrate adjacent to a dam structure. In conclusion, even under a high temperature environment, on an area adjacent to the edge of the semiconductor substrate, the second protection pattern may be prevented from delamination from the first semiconductor pattern, which may result in an improvement in structural stability of the semiconductor package.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope and spirit of the present inventive concepts.

What is claimed is

1. A semiconductor package, comprising:
a package substrate; and
an image sensor chip on the package substrate,
wherein the image sensor chip comprises:
a semiconductor substrate;
a light-shielding pattern on the semiconductor substrate;
a plurality of microlenses on the light-shielding pattern; and
a first protection pattern on the plurality of microlenses,
wherein the light-shielding pattern extends in a first direction parallel to a top surface of the semiconductor substrate, and
wherein a portion of a top surface of the light-shielding pattern is exposed by the first protection pattern.

2. The semiconductor package of claim 1, further comprising:
a transparent substrate on the image sensor chip; and
a dam structure on an edge of the image sensor chip and between the image sensor chip and the transparent substrate,
wherein the dam structure is spaced apart in the first direction from the first protection pattern.

3. The semiconductor package of claim 2, further comprising an upper planarization layer between the light-shielding pattern and the plurality of microlenses, wherein the first protection pattern is on a lateral surface of the upper planarization layer.

4. The semiconductor package of claim 3, further comprising a second protection pattern between the light-shielding pattern and the upper planarization layer,
wherein the second protection pattern is on a lateral surface of the light-shielding pattern.

5. The semiconductor package of claim 4, wherein
the first protection pattern comprises at least one selected from silicon oxide, titanium oxide, zirconium oxide, or hafnium oxide, and
wherein the second protection pattern comprises aluminum oxide.

6. The semiconductor package of claim 4, wherein one end of the second protection pattern is closer than one end of the first protection pattern to an edge of the semiconductor substrate.

7. The semiconductor package of claim 4, wherein a portion of the second protection pattern is in contact with the dam structure.

8. A semiconductor package, comprising:
a package substrate;
an image sensor chip on the package substrate;
a transparent substrate on the image sensor chip; and
a dam structure on an edge of the image sensor chip and between the image sensor chip and the transparent substrate,
wherein the image sensor chip comprises:
a semiconductor substrate;
a light-shielding pattern on the semiconductor substrate;
an upper planarization layer on the light-shielding pattern;
a plurality of microlenses on the upper planarization layer; and
a first protection pattern on the plurality of microlenses and a lateral surface of the upper planarization layer,
wherein the dam structure has a first lateral surface and an opposite second lateral surface,
wherein the dam structure first lateral surface is closer than the dam structure second lateral surface to the plurality of microlenses,
wherein a distance in a first direction from the dam structure second lateral surface to the first protection pattern has a first length, wherein the first direction is parallel to a top surface of the semiconductor substrate,
wherein a distance in the first direction from the dam structure first lateral surface to the first protection pattern has a second length, and
wherein the second length is about 20% to about 35% of the first length.

9. The semiconductor package of claim 8, wherein
the first length is in a range of about 450 μm to about 500 μm, and
the second length is in a range of about 100 μm to about 150 μm.

10. The semiconductor package of claim 8, wherein the dam structure first lateral surface is between one end of the first protection pattern and a lateral surface of the light-shielding pattern.

11. The semiconductor package of claim 8, wherein a bottom surface of the first protection pattern is at a level higher than a level of a top surface of the light-shielding pattern.

12. The semiconductor package of claim 8, wherein a bottom surface of the first protection pattern is spaced apart from the semiconductor substrate.

13. The semiconductor package of claim 8, wherein
a lateral surface of the upper planarization layer comprises a stepwise structure, and
the first protection pattern is on the stepwise structure.

14. The semiconductor package of claim 8, further comprising a second protection pattern on a top surface and a lateral surface of the light-shielding pattern,
wherein a portion of the second protection pattern is in contact with the dam structure.

15. The semiconductor package of claim 14, wherein
a thickness of the first protection pattern is in a range of about 100 nm to about 120 nm, and
a thickness of the second protection pattern is in a range of about 10 nm to about 20 nm.

16. The semiconductor package of claim 14, wherein
the semiconductor substrate comprises a conductive pad adjacent to an edge of the semiconductor substrate, and
the conductive pad is closer to the second protection pattern than to the first protection pattern.

17. A semiconductor package, comprising:
a package substrate;
an image sensor chip on the package substrate;
a transparent substrate on the image sensor chip; and
a dam structure on an edge of the image sensor chip and between the image sensor chip and the transparent substrate,
wherein the image sensor chip comprises:
a semiconductor substrate that comprises a pixel array region and a pad region extending around a periphery of the pixel array region, wherein the pixel array region comprises a light-receiving section and a light-shielding section between the light-receiving section and the pad region;
a light-shielding pattern on the light-shielding section;
an upper planarization layer on the light-receiving section and the light-shielding section, wherein the upper planarization layer is on a portion of the light-shielding pattern;
a plurality of microlenses on the upper planarization layer; and
a first protection pattern on the plurality of microlenses and a lateral surface of the upper planarization layer,
wherein the first protection pattern extends onto the light-shielding section, and
wherein one end of the first protection pattern is between the plurality of microlenses and the dam structure.

18. The semiconductor package of claim 17, further comprising a second protection pattern on a top surface and a lateral surface of the light-shielding pattern,
wherein one end of the second protection pattern is between the one end of the first protection pattern and an outer lateral surface of the dam structure.

19. The semiconductor package of claim 17, wherein a distance in a first direction from the outer lateral surface of the dam structure to the first protection pattern is in a range of about 450 μm to about 500 μm, wherein the first direction is parallel to a top surface of the semiconductor substrate.

20. The semiconductor package of claim 17, wherein the plurality of microlenses do not vertically overlap the dam structure.
